(19) United States
(12) Patent Application Publication
(10) Pub. No.: US 2009/0322419 A1
(43) Pub. Date: Dec. 31, 2009

(54) AMPLIFYING APPARATUS USING MAGNETO-RESISTIVE DEVICE

(75) Inventors: Hiroki Maehara, Tokyo (JP); Hitoshi Kubota, Tsukuba-shi (JP); Akio Fukushima, Tsukuba-shi (JP); Shinji Yuasa, Tsukuba-shi (JP); Yoshishige Suzuki, Osaka (JP); Yoshinori Nagamine, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/506,201

(22) Filed: Jul. 20, 2009

Related U.S. Application Data
(63) Continuation of application No. PCT/JP2007/069926, filed on Oct. 12, 2007.

(51) Int. Cl. H03F 1/00

(52) U.S. Cl. 330/60

(57) ABSTRACT

An amplifying apparatus includes a magneto-resistive device which has a magnetic free layer, a magnetic pinned layer having a magnetic moment larger than that of the magnetic free layer, and an intermediate layer provided in between the magnetic free layer and the magnetic pinned layer. The amplifying apparatus has a first electrode layer provided in a magnetic free layer side of the magneto-resistive device, and a second electrode layer provided in a magnetic pinned layer side of the magneto-resistive device. The amplifying apparatus further includes a direct-current bias power-source for applying a direct-current bias to the magneto-resistive device, and a load resistor. The amplifying apparatus continually causes the change of a magnetization direction of the magnetic free layer to make the magneto-resistive device show negative resistance, and thereby amplifies an input signal.

### CROSS-REFERENCES TO RELATED APPLICATIONS

This application is a continuation application of International Application No. PCT/JP2007/069926, filed on Oct. 12, 2007, the entire contents of which are incorporated by reference herein.

### TECHNICAL FIELD

The present invention relates to an amplifying apparatus using a magneto-resistive device.

### BACKGROUND ART

A tunnel diode represented by an Esaki diode is known as a conventional negative-resistance device (for instance, in Patent Document 1). The negative resistance exhibited by the tunnel diode originates in a tunnel phenomenon, and in the case of the Esaki diode, for instance, the negative resistance is realized by enhancing impurity concentrations of P type and N type in a PN junction diode.

FIG. 1 illustrates current/voltage characteristics of an Esaki diode which has been prepared from various materials (Ge, GaSb, Si and GaAs). FIG. 2 schematically illustrates these characteristics. Reference numeral 21 in FIG. 2 denotes a negative-resistance region which exists in current/voltage characteristics. Such a device as showing a negative resistance which is specific electrical conduction characteristics can be used as an amplifier.

It is also proposed to use a magneto-resistive effect device as a magnetic memory device, which has a ferromagnetic tunnel junction having a first ferromagnetic layer, an insulation layer and a second ferromagnetic layer stacked therein (for instance, in Patent Document 2). The magneto-resistive effect device also has current/voltage characteristics including a negative-resistance region.

Patent Document 1: Japanese Patent Publication No. S35-006326

### Patent Document 2: Japanese Patent Application Laid-Open No. 2004-158750

Current/voltage characteristics of an Esaki diode is expressed by the sum of electric current components having three different components of a tunnel current, an excessive current and a diffusion current. Therefore, the current/voltage characteristics show not only an excellent linear region but also a non-linear region over a wide range as is illustrated in a region 22 in FIG. 2. Such existence of a non-linear region causes a problem that when the diode is applied to an amplifying apparatus, the amplifying apparatus cannot obtain a stable gain.

The Esaki diode also determines a voltage region showing negative resistance by a band gap of a material. Accordingly, the voltage region developing the negative resistance is determined by the material, so that negative-resistance devices having different voltage regions of negative resistance cannot be prepared by the same materials. For this reason, amplifying apparatuses which primarily work with different current biases cannot be realized by using the same materials.

A magneto-resistive effect device having a ferromagnetic tunnel junction disclosed in Patent Document 2 also shows the negative resistance, but the current/voltage characteristics include a large non-linear region similar to the Esaki diode. Accordingly, when the device is applied to an amplifying apparatus, the amplifying apparatus cannot obtain a stable gain.

The present invention has been designed so as to solve such a problem, and is directed at providing a two-terminal type negative-resistance device which causes the negative resistance by a principle different from that of a tunnel effect, and realizing an amplifier using the device having a negative-resistance region excellent in linearity. The present invention is also directed to amplifying devices which work with various direct-current biases by using the same materials.

### SUMMARY OF THE INVENTION

A magneto-resistive device includes a magnetic free layer, an intermediate layer and a magnetic pinned layer generates negative resistance in the current/voltage characteristics of the magneto-resistive device. In the device, an electric current is flowed to a magnetic free layer side from a magnetic pinned layer side when magnetization directions of the magnetic free layer and the magnetic pinned layer form an acute angle (preferably being parallel), to suppress the magnetization reversal of the magnetic free layer generated by a spin torque, with an effective field and a voltage control. In this way, the magnetization reversal continuously takes place. An amplifying apparatus can be realized by using such a magneto-resistive device.

The amplifying apparatus according to the present invention an amplifying apparatus comprises a magneto-resistive device including a magnetic free layer, a magnetic pinned layer having a magnetic moment larger than that of the magnetic free layer, and an intermediate layer provided between the magnetic free layer and the magnetic pinned layer, a first electrode layer provided in a magnetic free layer side of the magneto-resistive device; a second electrode layer provided in a magnetic pinned layer side of the magneto-resistive device; a DC bias source for applying a DC bias to the magneto-resistance device and a load resistance. The magneto-resistive device shows negative resistance by continually causing the change of a magnetization direction of the magnetic free layer, and thereby amplifies an input signal.

The magnetization direction of the magnetic free layer and the magnetization direction of the magnetic pinned layer form an acute angle in a state in which voltage is not applied to the magneto-resistive device. When a voltage is applied so as to make electrons flow from the first electrode layer, the change of the magnetization direction of the magnetic free layer continuously takes place, and thereby the magneto-resistive device exhibits a negative resistance.

For this purpose, the amplifying apparatus according to the present invention is configured to include means for applying a magnetic field to the magneto-resistive device so that the angle formed by the magnetization direction of the magnetic free layer and the magnetization direction of the magnetic pinned layer is stably acute or substantially parallel in a state in which the voltage is not applied to the magneto-resistive device.

Furthermore, the amplifying apparatus is be configured so that the means for applying the magnetic field is formed of a permanent magnetic layer, and the amplifying apparatus includes an insulation layer for insulating the permanent magnetic layer from the magneto-resistive device, the first electrode layer and the second electrode layer.

As another aspect, the amplifying apparatus can also be configured so as not to have means for applying the magnetic field. In this case, the amplifying apparatus is configured so that the intermediate layer has such a thickness as to make the magnetization direction of the magnetic free layer and the magnetization direction of the magnetic pinned layer stably form an acute angle.

In addition, a magneto-resistance ratio of the magneto-resistive device is preferably 100% or more.

Furthermore, the amplifying apparatus may fix the magnetization direction of the magnetic pinned layer by forming an anti-ferromagnetic layer adjacent to the magnetic pinned layer, and forming a stacked structure of an anti-ferromagnetic layer, a ferromagnetic layer and a non-magnetic layer.

An amplifying apparatus according to the present invention develops a negative resistance based on a principle that the negative resistance is generated originating from the deviation of the position of the balance of magnetization taken by adjustably managing the bias voltage. Accordingly, the magneto resistance device can provide a negative-resistance device having a negative-resistance region having a linearity more excellent than that of a conventional negative-resistance device. Accordingly, thereby realized amplifying apparatus can have stable amplification characteristics. In addition, amplifying apparatuses which work with various DC biases can be produced by using the same material.

### BRIEF DESCRIPTION OF THE DRAWINGS

FIG. 1 is a view illustrating current/voltage characteristics of an Esaki diode which has been prepared from various materials;

FIG. 2 is a schematic view illustrating current/voltage characteristics of an Esaki diode;

FIG. 3 is a view illustrating a configuration of a magneto-resistive device which is used as a negative-resistance device according to the present invention;

FIG. 4 is a view illustrating a configuration of a spin valve type of a magneto-resistive device which imparts a synthetic-anti-ferrocoupling to a magnetic pinned layer;

FIG. 5 is a view illustrating characteristics of resistance-external magnetic field of a spin valve type of a magneto-resistive device;

FIG. 6 is a view illustrating current/voltage characteristics, which is measured in a state where an external magnetic field has been applied to a magneto-resistive device so that the magneto-resistive device in FIG. 4 can be stable in a parallel state, and then the application of the external magnetic field is removed;

FIG. 7 is a view illustrating current/voltage characteristics measured after such an external magnetic field having been applied to a magneto-resistive device in FIG. 4 that the magneto-resistive device can be stable only at a parallel state;

FIG. 8 is a view illustrating one example of a configuration of a negative-resistance device having means for applying a magnetic field;

FIG. 9 is a view illustrating one example of a configuration of a negative-resistance device having means for applying a magnetic field;

FIG. 10 is a view illustrating characteristics of resistance-external magnetic field measured when a film thickness of an intermediate layer is thinner than that in FIG. 5;

FIG. 11 is a view illustrating the shift quantity of characteristics of resistance-external magnetic field measured when a film thickness of an intermediate layer 45 formed by MgO is varied;

FIG. 12 is a view illustrating current/voltage characteristics of magneto-resistive device having characteristics of resistance-external magnetic field In FIG. 10;

FIG. 13 is a view illustrating current/voltage characteristics of a magneto-resistive device in FIG. 4, of which the MR ratio is approximately 80%;

FIG. 14 is a view illustrating current/voltage characteristics of the magneto-resistive device in FIG. 4, of which the MR ratio is approximately 100%;

FIG. 15 is a view illustrating current/voltage characteristics of a magneto-resistive device in FIG. 4, in a case where the shape of a magnetic free layer is rectangular in a film plane direction, and a ratio of the long side to the short side is 2:1;

FIG. 16 is a view drawn by plotting a differential conductance (dI/dV) which has been measured by varying an external magnetic field applied to a magneto-resistive device;

FIG. 17 is a configuration example of an amplifying apparatus according to the present invention, which uses a magneto-resistive device; and

FIG. 18 is a graph showing a measurement result of a gain of an amplifying apparatus according to the present invention.

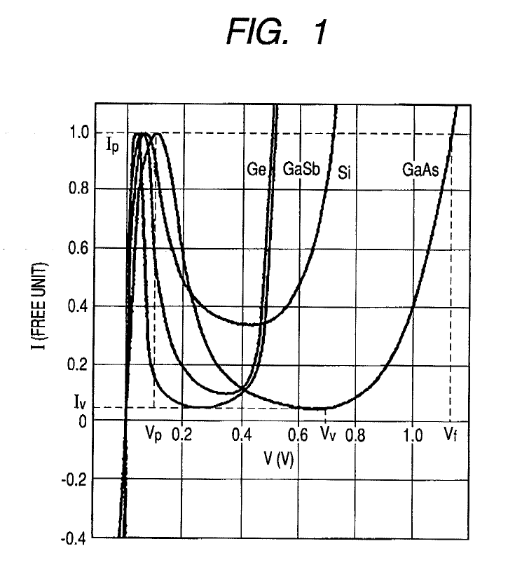

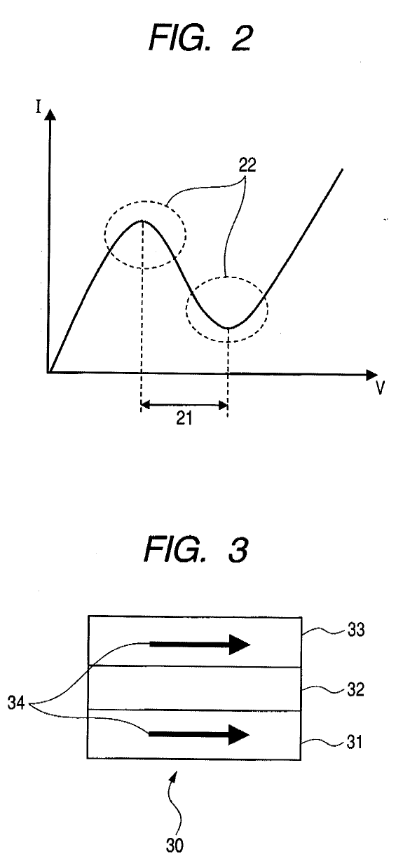

### DESCRIPTION OF REFERENCE NUMERALS FOR MAIN MEMBERS

21 negative-resistance region
22 non-linear region
30 magneto-resistive device
31 magnetic pinned layer
32 intermediate layer
33 magnetic free layer
34 magnetization directions of magnetic pinned layer and magnetic free layer
40 spin valve type of magneto-resistive device
41 anti-ferromagnetic layer
42 first magnetic pinned layer
43 non-magnetic layer
44 second magnetic pinned layer
45 non-magnetic layer (intermediate layer)
46 magnetic free layer
47 synthetic-anti-ferrocoupling
51 hysteresis region
80 negative-resistance device
81 magnetic pinned layer
82 intermediate layer
83 magnetic free layer
84, 85 electrode layer
86, 86a, 86b insulation layer
87, 87a, 87b permanent magnetic layer
88 direction of magnetic moment of magnetic pinned layer
89 magneto-resistive device
90 negative-resistance device
98 direction of magnetic moment of magnetic pinned layer
101 hysteresis region
170 amplifying apparatus
171, 172 electrode layer
173 negative-resistance device
174 direct-current bias power-source
175 alternating-current power-source
176 load resistor
177 capacitance
178 volt meter

### DETAILED DESCRIPTION OF EMBODIMENTS

In a negative-resistance device to be used in an amplifying apparatus according to the present invention, suppressing a magnetization reversal caused by an electronic spin injection in a magneto-resistive device generates a continual change to a magnetization direction. By doing this, a negative-resistance region appears in the current/voltage characteristics, and a negative-resistance device using a magneto-resistive effect is realized and can be used for the amplifying apparatus.

Among various characteristics of the negative resistance realized by the present invention, the value of characteristic voltage (threshold or start voltage of generating a negative resistance) is determined by a critical current value which causes a spin injection magnetization reversal, and a current ratio (peak valley ratio in current/voltage characteristics) is determined by a magneto resistance ratio exhibited by the magneto-resistive device. The negative-resistance region realized by the present invention originates in or is generated by the continuous change of such balanced position of magnetization. That is, the magnetization direction of the magnetic free layer is determined by a balance status between a torque given to the magnetic moment by an electrical bias. (namely, a force which intends to reverse the magnetic moment) and a force which intends to maintain the magnetic moment. Accordingly, shows better linearity than that in a conventional negative-resistance device.

At first, a configuration of a magneto-resistive device which shows a negative resistance and is used for an amplifying apparatus according to the present invention will now be described with reference to FIG. 3. A magneto-resistive device 30 includes a magnetic pinned layer 31, an intermediate layer 32 and a magnetic free layer 33, and has a structure in which the intermediate layer 32 is arranged between the magnetic pinned layer 31 and the magnetic free layer 33. In FIG. 3, magnetization directions of the magnetic pinned layer 31 and the magnetic free layer 33 are expressed by an arrow 34. The terms of “magnetic free layer” and “magnetic pinned layer” are referred to in the present specification hereafter in a definition that the magnetic moment of the magnetic free layer is smaller than that of the magnetic pinned layer.

The magneto-resistive device 30 functions as a negative-resistance device when a voltage to be applied to the magneto-resistive device is appropriately controlled. As an example, when the magnetic moment of the magnetic free layer 33 is parallel to that of the magnetic pinned layer 31 as is shown by the arrow 34 in FIG. 3, a voltage is applied to the magneto-resistive device 30 so as to make an electric current flow toward from a magnetic pinned layer 31 side in order to make electrons flow into from a magnetic free layer 33 side.

Furthermore, a voltage control is conducted so that the voltage applied to the magneto-resistive device 30 can be gradually increased. Actions of the magneto-resistive device 30 in the case of being thus controlled will now be described below.

(1) When the applied voltage increases, the value of an electric current flowing through the magneto-resistive device 30 also increases.

(2) When the current value increases, a spin torque applied to the magnetic moment of the magnetic free layer 33 increases.

(3) When a current value flowing through the negative-resistance device reaches a critical current value at which the magnetic free layer 33 causes a magnetization reversal (Hereinafter, the critical current value is referred to as I₁, and a voltage value applied to a device 30 is referred to as V₁.), the spin torque applied to the magnetic moment of the magnetic free layer 33 reaches a sufficient value (hereinafter referred to as f₁) so that the magnetic moment attempts to cause the magnetization reversal.

(4) When the magnetic moment of the magnetic free layer 33 is to be inverted, the magnetic moment of the magnetic free layer 33 and the magnetic moment of the magnetic pinned layer 31 deviate from a parallel state to each other. Then, the resistance value of the magneto-resistive device 30 increases due to the magneto-resistive effect.

(5) As the resistance value increases, the current value flowing through the magneto-resistive device 30 decreases. When the current value flowing through the device 30 is represented by I₂, and the voltage value to be applied is represented by V₂, the relationships satisfy I₂<I₁ and V₁<V₂, as long as the magnetic reluctance ratio (MR ratio) of the magneto-resistive device 30 is a large value to some extent, which will be described later. In other words, the gradient of current/voltage characteristics of the device 30 becomes negative, and a negative resistance is generated.

(6) As the current value flowing through the device 30 decreases, the quantity of electrons flowing for causing a spin torque applied to the magnetic moment of the magnetic free layer 33 also decreases. Thereby, the spin torque is weakened, and when the spin torque at this time is represented by f₂, the relationship satisfies f₂<f₁.

(7) Because the spin torque is weakened, the magnetic moment of the magnetic free layer 33 which is going to be inverted stops at such a position as to balance with an effective magnetic field.

(8) The voltage applied to the device 30 is controlled so as to gradually increase, so that the action returns to (1) again, and the actions of (1) to (7) are repeated. Every time the actions of (1) to (7) are repeated, the magnetic moment of the magnetic free layer 33 gradually moves to a state of being anti-parallel to the magnetic moment of the magnetic pinned layer 31.

As is described above, an amplifying apparatus according to the present invention causes a state in which the magnetization reversal of the magnetic free layer 33 continually occurs (in other words, a state in which the direction of the magnetic moment of the magnetic free layer 33 against the direction of the magnetic moment of the magnetic pinned layer 31 is continually changed to an anti-parallel state), by controlling the applied voltage so as to continually increase in the magneto-resistive device 30. As the control voltage continually increases, the resistance value of the device 30 also continually increases, so that the value of differential resistance becomes negative and a negative resistance can be realized. On the other hand, when the applied voltage is continually decreased in a voltage region in which the magneto-resistive device 30 shows negative resistance, the direction of the magnetic moment of the magnetic free layer 33 continually changes to a state of being parallel to the magnetic moment of the magnetic pinned layer 31 from a state of being anti-parallel. In this case, the resistance value of the device 30 continually decreases, so that the differential resistance value also becomes negative and the negative resistance can be realized.

However, in order to cause the magnetization reversal through a spin injection magnetization reversal in this way, the magnetic moment of the magnetic free layer 33 (ferromagnetic layer) causing the magnetization reversal needs to be smaller than the magnetic moment of the magnetic pinned layer 31, as is defined in the above description in the present specification.

Furthermore, the present inventors have found an important condition for realizing a negative-resistance device with the use of a magneto-resistive device 30. An experiment in which the condition has been found will now be described below.

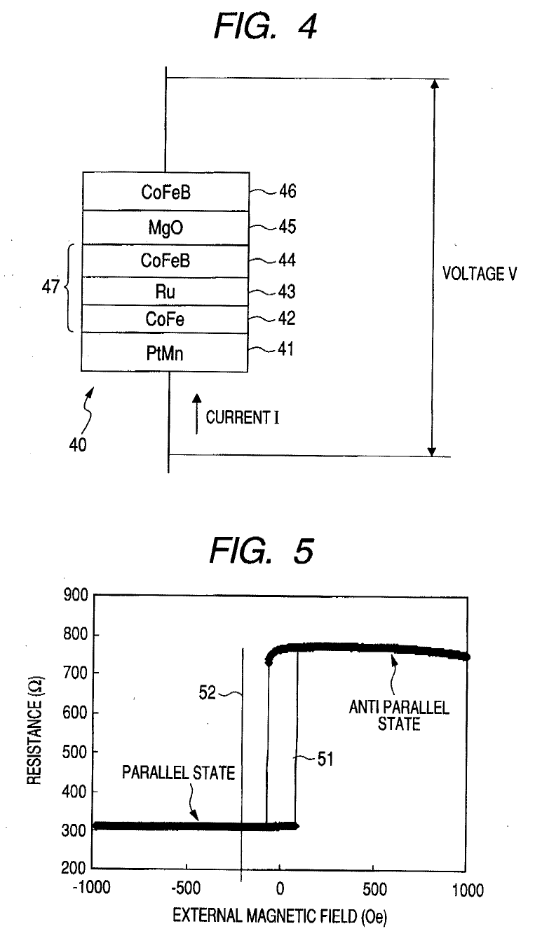

FIG. 4 illustrates a spin valve type of a magneto-resistive device 40 in which synthetic-anti-ferrocoupling is provided in a magnetic pinned layer, as a magneto-resistive device which can be used in the present invention. The magneto-resistive device 40 has a structure in which an anti-ferromagnetic layer 41 formed from platinum manganese (PtMn), a first magnetic pinned layer 42 that is a ferromagnetic layer formed from ferrocobalt (CoFe), a non-magnetic layer 43 formed from ruthenium (Ru), a second magnetic pinned layer 44 that is the ferromagnetic layer formed from ferrocobaltboron (CoFeB), a non-magnetic layer (intermediate layer) 45 formed from magnesium oxide (MgO) and a magnetic free layer 46 formed from CoFeB are stacked. The second magnetic pinned layer 44, the intermediate layer 45 and the magnetic free layer 46 correspond to the magnetic pinned layer 31, the intermediate layer 32 and the magnetic free layer 33 in FIG. 3, respectively. The first magnetic pinned layer 42, the non-magnetic layer 43 and the second magnetic pinned layer 44 constitute synthetic-anti-ferrocoupling. The magnetization direction of the second magnetic pinned layer 44 is fixed by forming the anti-ferromagnetic layer 41, the first magnetic pinned layer 42 and the non-magnetic layer 43 adjacent to the second magnetic pinned layer 44. Only an anti-ferromagnetic layer 41 is formed adjacent to the second magnetic pinned layer 44, as another configuration.

Hereafter, in the present exemplary embodiment, a magneto-resistive device 40 was set at the square shape of approximately 100 nm in longitudinal and transverse directions in a film plane (direction parallel to film surface). In addition, as for the thicknesses of each layer, an anti-ferromagnetic layer 41 was set at 15 nm, a first magnetic pinned layer 42 at 3 nm, a non-magnetic layer 43 at 0.85 nm, a second magnetic pinned layer 44 at 3 nm, an intermediate layer 45 at 1.1 nm, and a magnetic free layer 46 at 2 nm. The magnetic free layer 46 is formed so as to have a magnetic moment smaller than the second magnetic pinned layer 44, by making the magnetic free layer 46 thinner than the second magnetic pinned layer 44.

FIG. 5 illustrates characteristics of resistor-external magnetic field (R-H) in the spin valve type of the magneto-resistive device 40. When an external magnetic field of the inside of a hysteresis region 51 is applied to the magneto-resistive device 40 (for instance, when external magnetic field is zero), the magnetic free layer 46 and the magnetic pinned layer 47 can select any magnetization direction of a state of being parallel (low resistance value) to each other and a state of being anti-parallel (high resistance value) to each other as a stable point. Hereafter, in the present exemplary embodiment, current/voltage characteristics of the magneto-resistive device 40 shall be measured in a state in which the magnetization direction of the magnetic free layer 46 and the magnetization direction of the magnetic pinned layer 47 are set at a parallel state.

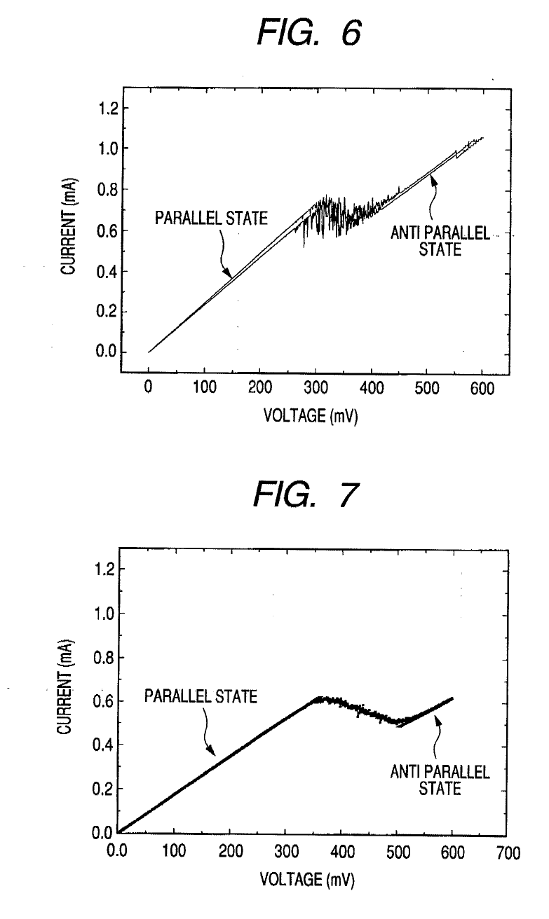

Firstly, the external magnetic field was applied to the magneto-resistive device so that the magnetization directions became stable in a parallel state, then the external magnetic field was cancelled, and the current/voltage characteristics were measured in the state (the external magnetic field was zero). The measurement result is shown in FIG. 6. When the current value flowing through the magneto-resistive device 40 reached the critical current value of the magnetic free layer 46, and started the magnetization reversal in the magnetic free layer 46, the resistance value of the magneto-resistive device 40 changed at random and did not show a clear tendency of negative resistance, as is shown in FIG. 6. This is considered to be because both of the parallel state and the anti-parallel state can be stable in an effective magnetic field of the present experimental condition as is illustrated in FIG. 5, the magnetization direction of the magnetic free layer jumps from the parallel state to the anti-parallel state or the anti-parallel state to the parallel state by receiving a heat energy caused by the bias application, and accordingly does not continually cause the magnetization reversal.

It was found from this experiment that when the value of the effective magnetic field sensed by the magneto-resistive device is in the inside of the hysteresis region (for instance, 51 in FIG. 5) of the R-H characteristics, in other words, when the magnetization direction of the magnetic free layer and the magnetization direction of the magnetic pinned layer can be stable both in a state of being parallel to each other and a state of being anti-parallel to each other, an adequate negative resistance cannot be realized by controlling the applied voltage.

Subsequently, the external magnetic field to be applied to the magneto-resistive device 40 in FIG. 4 was set at the point of 52 as illustrated in FIG. 5, and the current/voltage characteristics were measured in a state in which the magnetization directions were stable only in a parallel state. The measurement result is shown in FIG. 7. Thus, a continuous change of the magnetization direction to the anti-parallel state from the parallel state in the magnetic free layer can be caused by controlling the applied voltage so as to gradually increase, and further reducing the magnetization reversal due to the external magnetic field, and the negative resistance can be thereby realized. The negative-resistance region in FIG. 7 shows adequate linearity, and a problem of non-linearity is improved in comparison with a conventional negative-resistance device. Thus, the negative-resistance device using a magneto-resistive effect according to the present invention can show a stable negative resistance by setting an appropriate applied magnetic field, and can provide a stable gain when being applied to an amplifier.

As is described above, in order to obtain a stable negative resistance in the present invention, it is necessary to control the magnetization direction of the magnetic free layer of a magneto-resistive device which is used in a negative-resistance device so as to be stable only in a state of being parallel to the magnetization direction of a magnetic pinned layer.

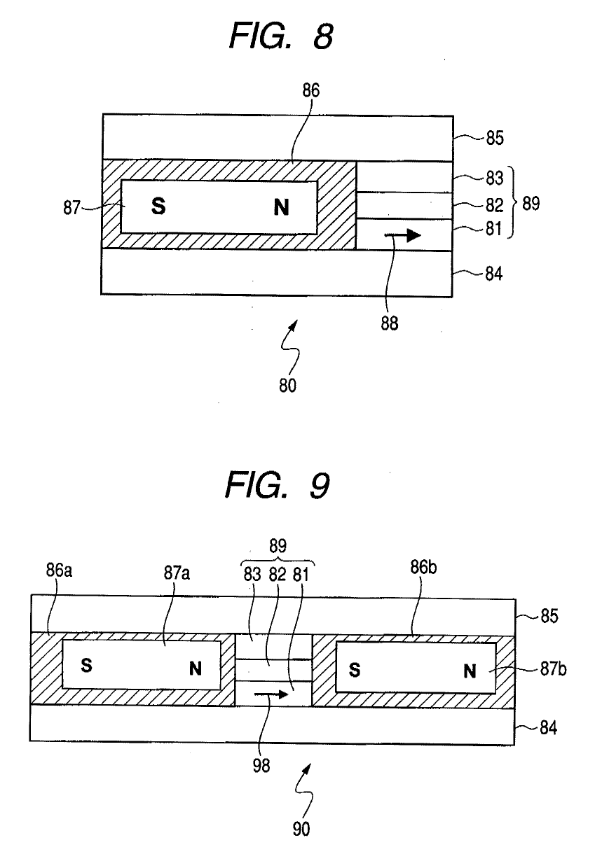

An example of the negative-resistance device satisfying such a condition is illustrated in FIG. 8. A negative-resistance device 80 in FIG. 8 includes a magneto-resistive device 89 including a magnetic pinned layer 81, an intermediate layer 82 and a magnetic free layer 83, and electrode layers 84 and 85 for applying voltage to the magneto-resistive device 89. The electrode layers 84 and 85 are formed from a metal such as copper and gold having high electroconductivity. The negative-resistance device 80 is further provided with means for applying the external magnetic field to the magneto-resistive device 89 in the vicinity of the magneto-resistive device 89. For instance, a permanent magnetic layer 87 is provided on one side of the magneto-resistive device 89, and an insulation layer 86 is provided between the permanent magnetic layer 87 and each of the electrode layers 84 and 85 and the magneto-resistive device 89 so that the electrode layers do not form a short circuit.

In FIG. 8, a direction of the magnetic moment of the magnetic pinned layer 82 is set at a right hand direction as is shown by an arrow 88. As is described above, the magnetization direction of the magnetic free layer 83 needs to be stable only in a state of being parallel to the magnetization direction of the magnetic pinned layer 81 as a stable point, so that a side near to the magneto-resistive device 89 of the permanent magnetic layer 87 is set at an N pole, and a far side thereof is set at an S pole in FIG. 8. By being arranged in such a configuration, the means can apply the external magnetic field to the magnetic free layer so that the magnetic moment of the magnetic free layer can direct in the same direction as the magnetic moment of the magnetic pinned layer 81 (direction of arrow 88), and can apply the external magnetic field so that the magnetic moment of the magnetic free layer 83 is in a state of being parallel to the magnetic moment of the magnetic pinned layer 81. The device 80 functions as a negative-resistance device by applying voltage to the magneto-resistive device 89 so that an electric current can flow from a magnetic pinned layer 81 side through the electrode layers 84 and 85, and controlling the applied voltage so that the applied voltage increases.

A negative-resistance device according to the present exemplary embodiment can function even when a permanent magnetic layer 87 is arranged only in one side of a magneto-resistive device 89, but the permanent magnetic layer can be arranged in both sides of the magneto-resistive device 89. The negative-resistance device having such a configuration is illustrated in FIG. 9. The negative-resistance device 90 in FIG. 9 includes the magneto-resistive device 89, electrode layers 84 and 85 all in FIG. 8, permanent magnetic layers 87a and 87b arranged in both sides of the magneto-resistive device 89, and insulation layers 86a and 86b. An arrow 98 shows the direction of the magnetic moment of a magnetic pinned layer 81. A side near to the magneto-resistive device 89 of the permanent magnetic layer 87a is set at an N pole, and a side near to the magneto-resistive device 89 of the permanent magnetic layer 87b is set at an S pole. The configuration in FIG. 9 can apply a magnetic field having more uniform magnetic flux to the magneto-resistive device 89 than that in FIG. 8.

The negative-resistance device according to the present exemplary embodiment described in the above is configured so that the magnetization direction of a magnetic free layer of a magneto-resistive device can be parallel to the magnetization direction of a magnetic pinned layer (that is to say, an angle formed by the magnetization directions of these layers can be 0 degree), in a state in which voltage is not applied to the magneto-resistive device. However, the negative-resistance device according to the present exemplary embodiment is not limited to such a configuration, as long as an angle formed by the above described two magnetization directions is an acute angle. Thereby, a spin torque is applied to the magnetic moment of the magnetic free layer, and the negative resistance can be realized.

In the above described example, the negative-resistance device is configured so as to continually cause the magnetization reversal by realizing a state in which the magnetization directions of the magnetic free layer and the magnetic pinned layer can be stable only when the magnetization directions are parallel to each other, through applying the external magnetic field to the magneto-resistive device, and by reducing the magnetization reversal of the magnetic free layer. However, the magnetization reversal can be also reduced by using a shift of the hysteresis region in characteristics of resistance-external magnetic field instead of applying the external magnetic field.

The example will now be described with reference to the spin valve type of a magneto-resistive device 40 illustrated in FIG. 4. A hysteresis region 51 illustrated in FIG. 5 is shifted to right and left on the graph by changing the film thickness of an intermediate layer 45 of a magneto-resistive device 40 (making the layer thick or thin). Characteristics of resistance-external magnetic field (R-H) shown when the intermediate layer 45 was thinned into approximately 1.02 nm which was thinner than that in FIG. 5 are illustrated in FIG. 10. It is understood that a hysteresis region 101 shifts to a direction of preferring a parallel state more (right direction of graph).

The reason of causing such a shift is because a Neel coupling makes a magnetic free layer 46 and a magnetic pinned layer 47 form ferromagnetic coupling when the intermediate layer 45 is formed of MgO as is illustrated in FIG. 4. Here, the Neel coupling means an interaction occurring between the intermediate layer and the magnetic free layer when the surface of the intermediate layer of the magneto-resistive device has unevenness (in other words, roughness) and the like thereon.

In addition, when the intermediate layer is made from a metal such as copper, for instance, it is also possible to make an interlayer coupling due to an RKKY interaction cause an anti-ferromagnetic coupling between the magnetic free layer and the magnetic pinned layer, by changing the film thickness of the intermediate layer of the magneto-resistive device. In this case as well, the hysteresis region in the R-H characteristics shifts to right and left. Here, the RKKY interaction means an interaction caused by a free electron of a non-magnetic atom constituting a non-magnetic layer, which mediates a magnetic interaction between local magnetic moments of the ferromagnetic atom constituting the ferromagnetic layer.

In addition, when a size of the magneto-resistive device in a film surface direction (direction parallel to film surface) reaches a size in which the dimension of an edge domain cannot be ignored, the anti-ferromagnetic coupling occurs due to dipole coupling between the magnetic free layer and the magnetic pinned layer.

The shift of the above described hysteresis is expressed by the sum of these coupled magnetic fields. Therefore, the hysteresis is shifted to such a direction as a parallel state is preferred (right direction in FIG. 5) in a state in which the external magnetic field is not applied (in which the external magnetic field is zero), by intensifying the Neel coupling. In addition, the hysteresis is shifted to such a direction as an anti-parallel state is preferred (left direction in FIG. 5) in a state in which the external magnetic field is not applied, by intensifying the interlayer coupling due to the RKKY interaction or the dipole coupling.

In this way, it is possible to realize a state in which only a parallel state or only an anti-parallel state is stable, without applying the external magnetic field to the magneto-resistive device, by controlling the strength of a coupling force, and the magneto-resistive device becomes possible to be used as a negative-resistance device.

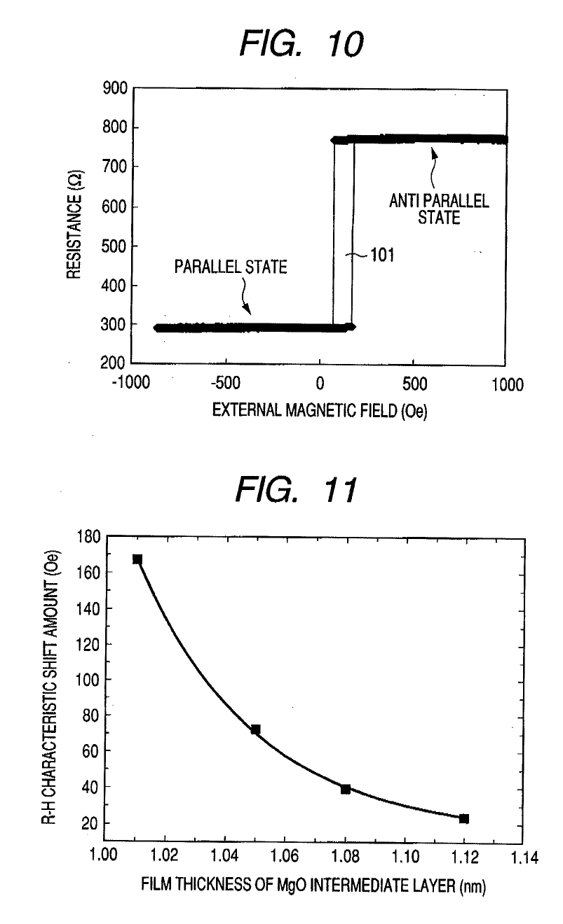

As an example, magneto-resistive devices 40 were prepared by changing the film thickness of the intermediate layer 45 formed from MgO and setting the size of the device in the film plane direction at approximately 100 nm×100 nm. A shifted amount in the R-H characteristics is shown in FIG. 11. In this case, the size of the magneto-resistive device 40 in the plane direction reaches a size in which the dimension of the edge domain cannot be ignored, so that the shifted amount of the magnetic field is expressed by a synthesized value of the Neel coupling and the dipole coupling. As can be understood from the result in FIG. 11, the R-H characteristics can be shifted by changing the film thickness of the intermediate layer.

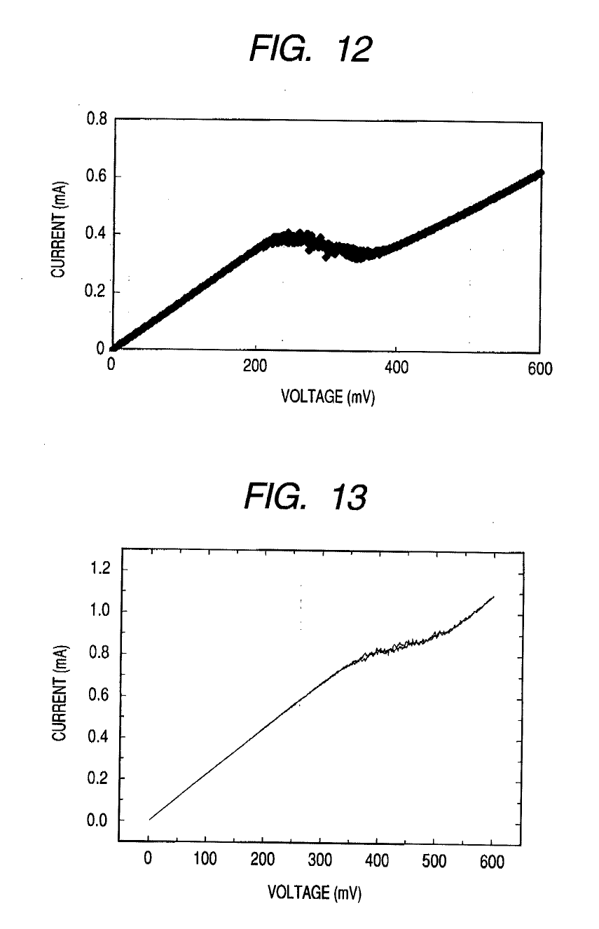

FIG. 12 shows current/voltage characteristics of a magneto-resistive device 40 having R-H characteristics in FIG. 10. An external magnetic field is not applied. As is shown in FIG. 10, the state in which only a parallel state is a stable point can be formed, by shifting the hysteresis region in the R-H characteristics without applying the external magnetic field. Accordingly, the magnetization reversal is effectively reduced even in a state free from the external magnetic field, and the magnetization reversal continually occurs, so that a negative-resistance region clearly appears in the current/voltage characteristics, as is shown in FIG. 12. Thus, the magneto-resistive device having the film thickness of the intermediate layer adequately set according to the present invention functions as a negative-resistance device, even without including permanent magnetic layers 87, 87a and 87b as illustrated in FIG. 8 and FIG. 9.

In the present exemplary embodiment, a magnetization direction of a magnetic free layer of a magneto-resistive device in a state in which voltage is not applied is not necessarily parallel to a magnetization direction of a magnetic pinned layer, but has only to form an acute angle.

When R_{P} is defined as an electric resistance of a magneto-resistive device in which the magnetization direction of the magnetic free layer is parallel to that of the magnetic pinned layer, and R_{AP} is defined as an electric resistance of a magneto-resistive device in which the magnetization direction is anti-parallel, a magnetic reluctance ratio (MR ratio) of the magneto-resistive device is defined as (R_{AP}−R_{P})/R_{P}. A peak valley ratio in current/voltage characteristics is determined by the magnitude of the magnetic reluctance ratio. Therefore, the peak valley ratio can be increased by using a magneto-resistive device showing a large magnetic reluctance ratio, and accordingly the negative-resistance device can be obtained which is suitable for application to an oscillator, an amplifier, a mixer, a switching device and the like. On the other hand, a magneto-resistive device showing a small magnetic reluctance ratio may not cause sufficient negative-resistance characteristics, even though the magnetization in the magnetic free layer would continually change.

FIG. 13 shows current/voltage characteristics measured on a magneto-resistive device 40 in which the MR ratio is set at approximately 80%. At this time, the current/voltage characteristics were measured on the condition of applying an external magnetic field to the device 40 so that only a parallel state can be a stable point similarly to the measurement time in FIG. 7, and gradually increasing the voltage to be applied thereto. In FIG. 13, a random change as shown in FIG. 6 is not seen, but it is understood that the magnetization direction of a magnetic free layer 46 in the magneto-resistive device 40 continually changes from a parallel state with respect to the magnetization direction of the magnetic pinned layer 47 to an anti-parallel state. However, because the MR ratio is small, the magneto-resistive device does not make differential resistance negative, and does not show negative resistance.

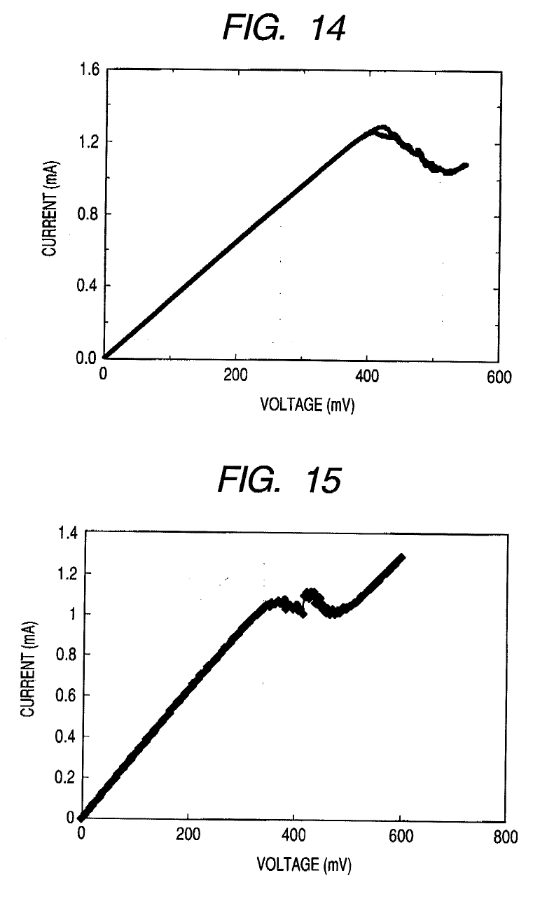

FIG. 14 shows current/voltage characteristics measured in the same condition on a magneto-resistive device 40 in which the MR ratio is set at approximately 100%. It is understood that when the MR ratio becomes approximately 100%, the magneto-resistive device 40 clearly shows the negative resistance. Thus, the magneto-resistive device according to the present invention needs a magnetic reluctance ratio which is large to some extent, in order to realize a negative-resistance device. The magnetic reluctance ratio is preferred to be approximately 100% or more.

A magneto-resistive device which has been described in the present invention has a structure in which an intermediate layer is formed on a magnetic pinned layer and a magnetic free layer is formed thereon. However, these layers have only to be arranged so that the magnetic free layer and the magnetic pinned layer sandwich the intermediate layer, and either of the magnetic free layer or the magnetic pinned layer may be in an upper position. When operating a negative-resistance device using the magneto-resistive device according to the present invention, the voltage to be applied to the magneto-resistive device is gradually increased until the voltage reaches a voltage region of showing the negative resistance, and then the applied voltage is controlled in a way of continually increasing or decreasing the voltage in the voltage region, as was described above. At this time, it is necessary to apply the voltage in a direction of making an electric current flow from a magnetic pinned layer side (in other words, in a direction of making electrons flow from a magnetic free layer side).

By the way, it is preferable to set the dimension of the magnetic free layer in a film plane direction (in direction parallel to film plane) (that is to say, dimension of magneto-resistive device in film plane direction) at 200 nm or smaller both in longitudinal and transverse directions. When employing the magnetic free layer having a larger dimension than the above dimension, the magneto-resistive device may not cause the magnetization reversal due to spin injection.

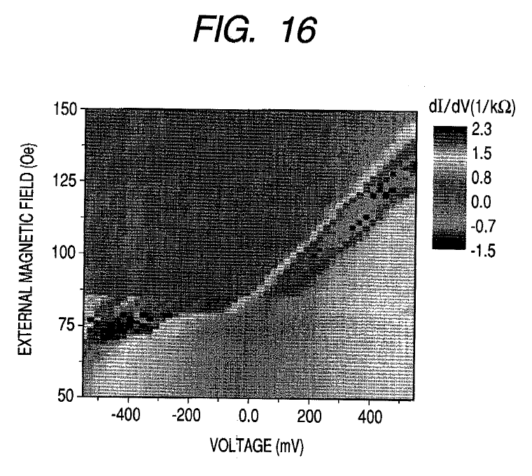

FIG. 15 shows current/voltage characteristics of a magneto-resistive device 40 provided with a magnetic free layer having a rectangular shape in a film plane direction, in which a ratio of the long side to the short side is 2:1, for instance. In FIG. 15, unstable negative-resistance characteristics are obtained. Accordingly, in order to obtain stable negative-resistance characteristics, the plane shape of the magneto-resistive device to be used for the negative-resistance device of the present invention is preferably an approximately circular or an approximately square.

Further, in a negative-resistance device using a magneto-resistance effect of the present invention, the voltage region in which negative resistance develops is not determined by a band gap of a material, which is different from the principle of an Esaki diode. The present invention can realize negative-resistance devices having different critical current values at which a magnetic free layer starts the magnetization reversal by using the same materials, through configuring the negative-resistance device so that the magnitudes of an external magnetic field to be applied to a magneto-resistive device are different from each other, or configuring the negative-resistance device so that the magnitudes of the magnetic moment of the magnetic free layer are different from each other. Accordingly, the present invention can produce negative-resistance devices having different voltage regions in which negative resistance develops from the same materials.

In order to show such an effect of the present invention, current/voltage characteristics were measured by varying an external magnetic field to be applied to the magneto-resistive device 40. FIG. 16 shows a view drawn by plotting a differential conductance (dI/dV) of the current/voltage characteristics, in which an abscissa shows voltage, and an ordinate shows an external magnetic field. As is understood from the measurement result, a voltage region in which negative resistance develops can be varied by varying the external magnetic field.

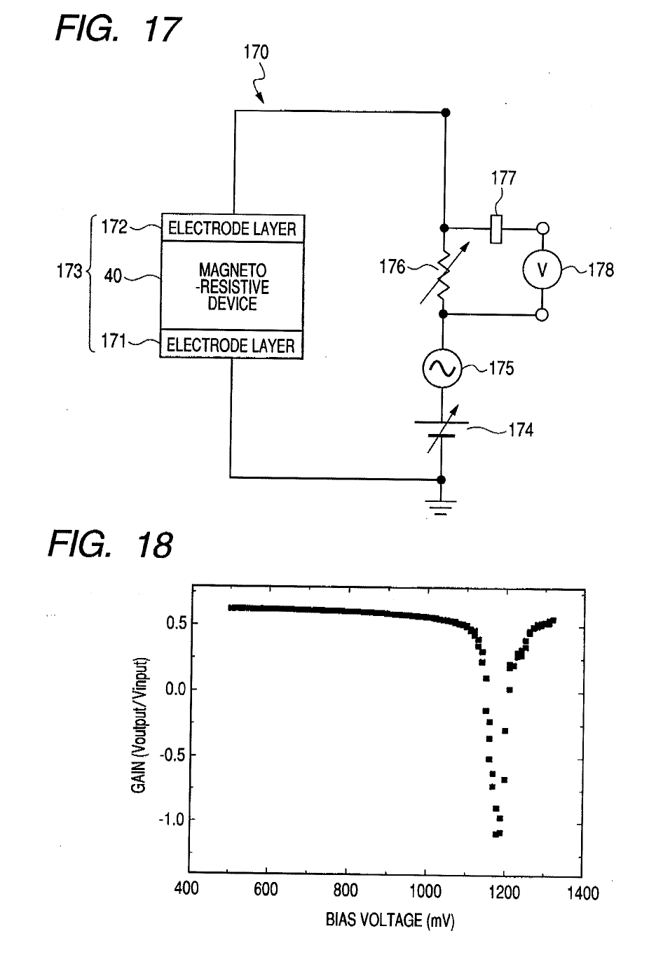

FIG. 17 illustrates a configuration example of an amplifying apparatus according to the present invention, which uses a negative-resistance device that is constituted by the magneto-resistive device described above. An amplifying apparatus 170 includes a negative-resistance device 173 having a first electrode layer 171 and a second electrode layer 172 provided on both ends of the magneto-resistive device 40, a direct-current bias power-source 174 and a load resistor 176. FIG. 17 further illustrates an alternating-current power-source 175, a capacitance 177 and a volt meter 178, which are prepared for measuring the amplification characteristics of the amplifying apparatus 170.

The magneto-resistive device 40 is structured in the same way as in FIG. 4. In the present exemplary embodiment, the film thickness of an anti-ferromagnetic layer 41 was set at 15 nm, the film thickness of a first magnetic pinned layer 42 at 2.5 nm, the film thickness of a non-magnetic layer 43 at 0.85 nm, the film thickness of a second magnetic pinned layer 44 at 3 nm, the film thickness of an intermediate layer 45 at 1.27 nm, and the film thickness of a magnetic free layer 46 at 2 nm. However, the combination of these film thicknesses is only one example. Various film thickness configurations other than the above combination can be adopted for the amplifying apparatus 170 of the present invention.

The direct-current bias power-source 174 is used for applying a direct-current bias to the magneto-resistive device 40 to make the magneto-resistive device 40 work in a negative-resistance region. The alternating-current power-source 175 generates an input signal which is to be amplified by the amplifying apparatus 170 in this experiment. An actual amplifying apparatus shall apply an input signal to be amplified in place of the alternating-current power-source 175 to a circuit in FIG. 17.

The load resistor 176 is a load for taking out an amplified input signal. In order to impart an amplifying function to the amplifying apparatus 170, the ohmic value of the load resistor 176 needs to be in a particular range, which will be described later. Accordingly, a variable resistor is used for the load resistor 176 in FIG. 17 so that the ohmic value can be adjusted. The capacitance 177 is used for removing a direct-current component from the voltage applied to both ends of the load resistor 176. The amplified alternating-current component is measured with the volt meter 178.

FIG. 18 shows a measurement result of a gain obtained by using a circuit configuration of FIG. 17, in which the frequency and effective value of the input signal (Vinput) that is applied by the alternating-current power-source 175 are set at 10 kHz and 20 mV respectively and the ohmic value of the load resistor 176 is set at 500 ω. At this time, the gain was measured by applying an external magnetic field to the magneto-resistive device 40 and making the magneto-resistive device stable only in a parallel state as is shown by reference numeral 52 in FIG. 5. In FIG. 18, an abscissa shows a bias voltage which is applied to the magneto-resistive device by the direct-current bias power-source 174. An ordinate shows a ratio (gain) of output voltage (Voutput) which has been measured by the volt meter 178 with respect to input voltage (Vinput) of the input signal which is generated by the alternating-current power-source 175. The phase of Voutput becomes a reversed phase of Vinput so that the gain shown in FIG. 18 is expressed by a negative value. It should be noted that the direct-current bias which is actually applied to the magneto-resistive device 40 is smaller than the value of the abscissa because the bias voltage of the abscissa is a direct-current bias which is applied to the whole circuit in FIG. 17.

It is understood from FIG. 18 that the absolute value of the gain exceeds 1 when the bias voltage is approximately 1,170 to 1,190 mV. This means that the amplifying apparatus 170 according to the present invention has amplified the input signal which has been applied to the negative-resistance device 173 by the alternating-current power-source 175 and has output the input signal. Accordingly, it was shown that an amplifying apparatus using a magneto-resistive device of the present invention had amplifying characteristics. In addition, the present inventors found a range of the ohmic value of the load resistor 176, which is necessary for the amplifying apparatus 170 of the present invention to show the amplifying characteristics. Specifically, the ohmic value R_{L} of the load resistor 176 needs to have a relationship of 1/2R_{D}<R_{L}<R_{D} with respect to a differential ohmic value R_{D} in a negative-resistance region of the magneto-resistive device 40.

In order to satisfy the relationship, firstly, the circuit needs to work stably. When a graphical solution is used, a static characteristics curve and a load curve of the magneto-resistive device need to intersect with each other at one point in the negative-resistance region. From the condition, the differential ohmic value R_{D} and the ohmic value R_{L} need to satisfy

|R_{D}(<0)|>R_{L} (1)

Furthermore, a degree of amplification is expressed by Gain=R_{L}/(R_{L}+R_{D}). Accordingly, by combining the expression with the condition of Expression (1), a relationship of 1/2R_{D}<R_{L}<R_{D} can be obtained.

In the above described experiment. R_{D} was approximately −700 ω and R_{L} was 500 ω. The values satisfied the above described relationship, so that the amplifying characteristics were confirmed.

In the present exemplary embodiment, an amplifying apparatus is realized by using a magneto-resistive device as illustrated in FIG. 4, but the configuration of an amplifying apparatus of the present invention is not limited to the above configuration. The amplifying apparatus 170 may be configured so as to further include means for applying an external magnetic field to the magneto-resistive device, as is illustrated in FIG. 8 and FIG. 9, for instance. Alternatively, the amplifying apparatus 170 can be realized without including means for applying the external magnetic field, as is described above, by configuring the magneto-resistive device so that an intermediate layer has such a thickness as to make the magnetization direction of a magnetic free layer stably parallel to the magnetization direction of a magnetic pinned layer.

An amplifying apparatus realized by the present invention can show amplifying characteristics excellent in linearity, by using a magneto-resistive device having a negative-resistance region having more excellent linearity than a conventional negative-resistance device using a tunnel effect. In addition, amplifying apparatuses according to the present invention can be produced by using the same materials so as to work at various direct-current biases.

1. An amplifying apparatus comprising:
a magneto-resistive device; including
a magnetic free layer,
a magnetic pinned layer having a magnetic moment larger than that of the magnetic free layer, and
an intermediate layer provided between the magnetic free layer and the magnetic pinned layer,
a first electrode layer provided in a magnetic free layer side of the magneto-resistive device;
a second electrode layer provided in a magnetic pinned layer side of the magneto-resistive device; and
a signal source circuit.
wherein the magneto-resistive device has the only stable state that the magnetization direction of the magnetic free layer and the magnetization direction of the magnetic pinned layer form an acute angle or are substantially parallel, when a voltage is not applied to the magneto-resistive element.

2. The amplifying apparatus according to claim 1, wherein the voltage is applied so as to make electrons flow from the first electrode layer to continually cause the change of the magnetization direction of the magnetic free layer, and thereby make the magneto-resistive device show negative resistance.

3. The amplifying apparatus according to claim 2, comprising means for applying a magnetic field to the magneto-resistive device so that the angle formed by the magnetization direction of the magnetic free layer and the magnetization direction of the magnetic pinned layer is stably acute in a state in which the voltage is not applied to the magneto-resistive device.

4. The amplifying apparatus according to claim 3, wherein the means for applying the magnetic field is formed of a permanent magnetic layer, and
The amplifying apparatus further comprises an insulation layer for insulating the permanent magnetic layer from the magneto-resistive device, the first electrode layer and the second electrode layer.

5. The amplifying apparatus according to claim 1, wherein the intermediate layer has such a thickness as to make the magnetization direction of the magnetic free layer and the magnetization direction of the magnetic pinned layer stably form an acute angle or are substantially parallel.

6. The amplifying apparatus according to claim 1, wherein the magneto-resistive device has a magnetic reluctance ratio of 100% or more.

7. The amplifying apparatus according to claim 1, wherein an anti-ferromagnetic layer is formed so as to be adjacent to the magnetic pinned layer.

8. The amplifying apparatus according to claim 1, wherein a stacked structure of an anti-ferromagnetic layer, a ferromagnetic layer and a non-magnetic layer is formed so as to be adjacent to the magnetic pinned layer.
